(19) United States
(12) Patent Application Publication
(10) Pub. No.: US 2012/0323506 A1
(43) Pub. Date: Dec. 20, 2012

(54) Semiconductor Defect Signal Capturing and Statistical System and Method

(76) Inventor: Andrew Payshin King, Lincoln, MA (US)

(21) Appl. No.: 13/214,609

(22) Filed: Oct. 13, 2011

Related U.S. Application Data
(60) Provisional application No. 61/416,352, filed on Nov. 23, 2010.

(51) Int. Cl. G06F 17/18; G01R 31/26

(52) U.S. Cl. 702/58

(57) ABSTRACT

This invention, embodied in software, is a defect signature detection and analysis system to group and classify defects received from semiconductor inspection tools into categories which identify the defect source. This system includes on-line monitoring devices, signal analytical and statistical devices and information database. The signal analytical device includes an analysis unit, capturing unit and an information queue. The capturing unit includes a number of sub-units, including sequential, overlap and iterative detection, grouping, and undefined signal detection. The system uniquely uses image processing techniques on non-image data to group individual defects into larger clusters, thereby increasing the probability of correct classification of the defect modes on semiconductor wafers, while decreasing incorrect or missing classifications. The system improves accuracy and integrity of these captured defect signals, enabling the statistical methods of the present invention to substantially replace the manual inspection of the prior art, and to decrease semiconductor manufacturing cost.

### CROSS-REFERENCE TO RELATED APPLICATIONS

Provisional patent application No. 61/416,352, filing date Nov. 23, 2010 and relating exactly to this non-provisional application

### STATEMENT REGARDING FEDERALLY SPONSORED RESEARCH OR DEVELOPMENT

Not applicable

### REFERENCE TO SEQUENCE LISTING, A TABLE, OR A COMPUTER PROGRAM LISTING COMPACT DISC APPENDIX

Not applicable

### BACKGROUND OF THE INVENTION

The present invention relates to the field of controlling the manufacture of semiconductor production, in particular to the field of detection and analysis in the control of the manufacture of semiconductor production, specifically to a semiconductor defect signal capturing and statistical system and method

### BRIEF SUMMARY OF THE INVENTION

A semiconductor defect signal capturing and statistical system, including an on-line monitoring device, characterized in that, said system further includes a defect signal analytical device, a defect information bank and a defect signal statistical device, the defect signal analytical device is connected with the on-line monitoring device, the defect information bank and the defect signal statistical device respectively, the defect information bank contains several pre-determined defect signal modes, the defect signal analytical device includes a defect signal analysis unit, a defect signal capturing unit and a defect information queue, the defect signal capturing unit includes a sequential detection sub-unit, an overlap detection sub-unit, an iterative detection sub-unit, a grouping detection sub-unit and an undefined signal detection sub-unit.

### BRIEF DESCRIPTION OF THE SEVERAL VIEWS OF THE DRAWING

FIG. 1 is the schematic view of the sub-unit structure of the defect signal capturing unit of the semiconductor defect signal capturing and statistical system according to the present invention.

FIG. 2 is a flow chart of the steps of the semiconductor defect signal capturing and statistical method carried out with the semiconductor defect signal capturing and statistical system of the present invention.

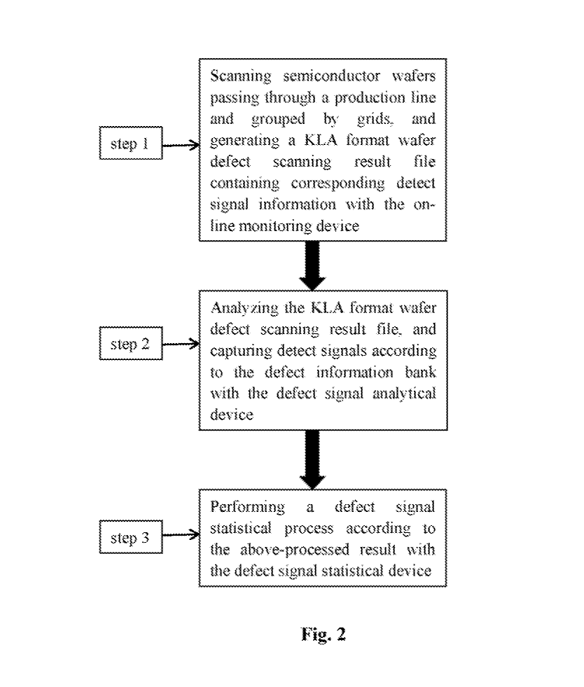

FIG. 3 is a flow chart of the steps of capturing defect signals with the sequential detection sub-unit of the defect signal capturing unit in the semiconductor defect signal capturing and statistical method of the present invention.

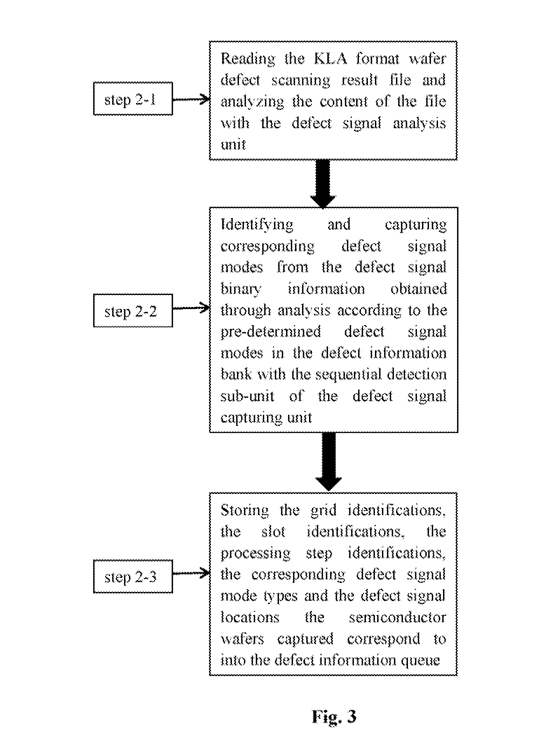

FIG. 4 is a flow chart of the steps of performing the iterative detection to the semiconductor defect signals uncaptured according to the semiconductor defect signals captured with the iterative detection sub-unit of the defect signal capturing unit in the semiconductor defect signal capturing and statistical method of the present invention.

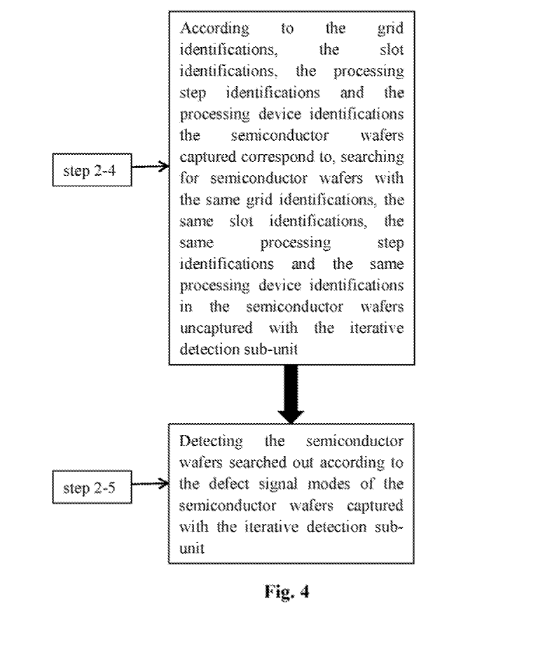

FIG. 5 is a flow chart of the steps of performing the iterative detection to the properties of the semiconductor defect signals uncaptured according to the properties of the semiconductor defect signals captured with the iterative detection sub-unit of the defect signal capturing unit in the semiconductor defect signal capturing and statistical method of the present invention.

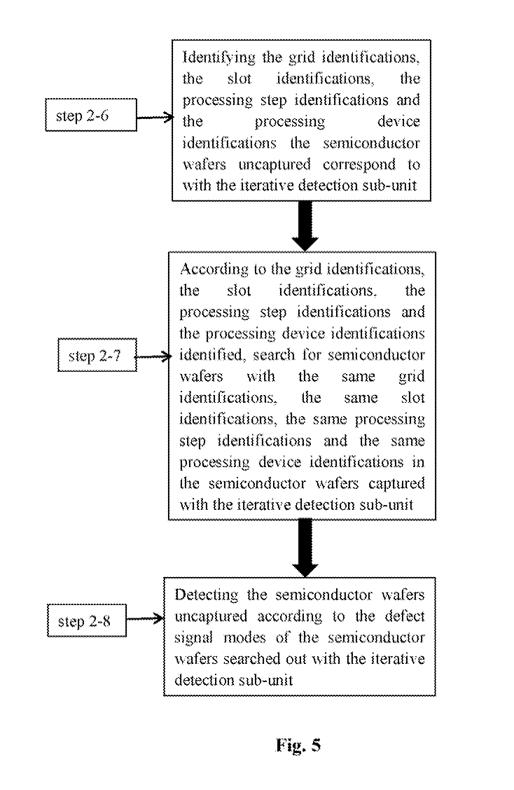

FIG. 6 is a flow chart of the steps of performing the grouping detection to the semiconductor defect signals uncaptured with the grouping detection sub-unit of the defect signal capturing unit in the semiconductor defect signal capturing and statistical method of the present invention.

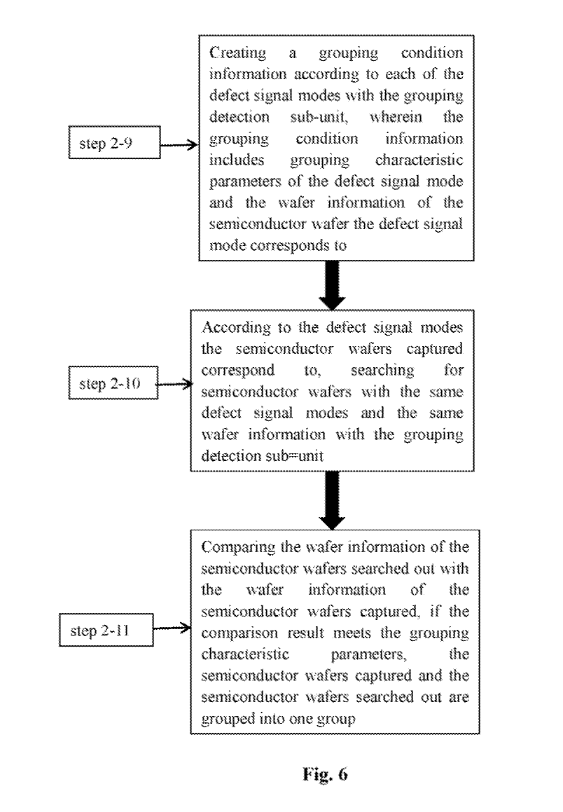

FIG. 7 is a flow chart of the steps of performing the overlap detection to the semiconductor defect signals uncaptured with the overlap detection sub-unit of the defect signal capturing unit in the semiconductor defect signal capturing and statistical method of the present invention.

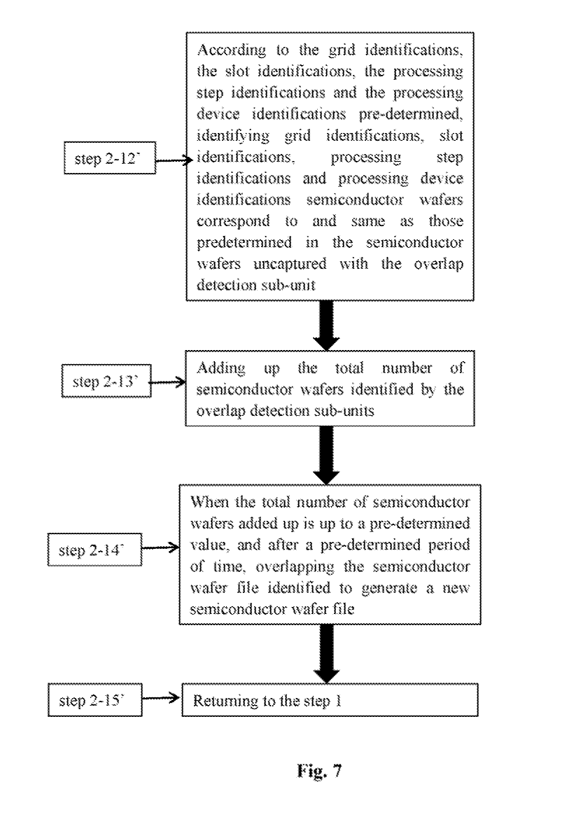

FIG. 8 is a flow chart of the steps of performing the undefined signal detection to the semiconductor defect signals uncaptured with the undefined signal detection sub-unit of the defect signal capturing unit in the semiconductor defect signal capturing and statistical method of the present invention.

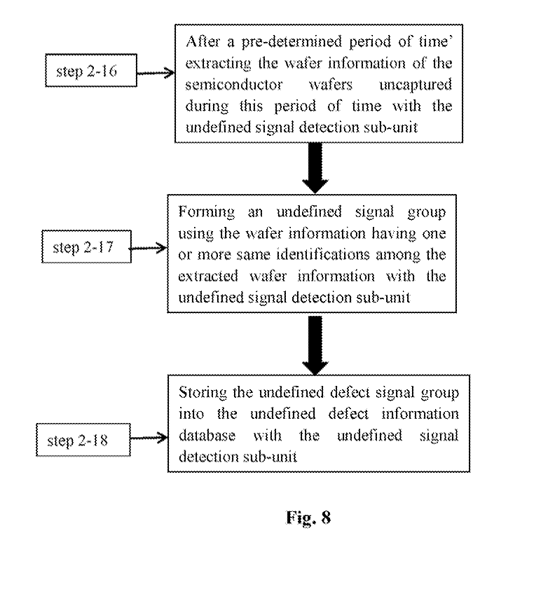

### DETAILED DESCRIPTION OF THE INVENTION

In order to understand the technical content of the present invention more clearly, the following embodiments are exemplified to clarify the present invention in details.

Due to the limitation of the accuracy of the algorithm itself and the limitation of the integrity of the defect signals, during the process of capturing and detecting defect signals, it is inevitable to generate various misreports and reports omitted, the problem of generating misreports and reports omitted cannot be solved substantially by only modifying the algorithm or enhancing the defect signals, on the premise of improving the accuracy of the algorithm and enhancing the identification rate of the defect signals, the present invention adopts new means unused in the industry to improve the accuracy and the integrity of the defect signals captured.

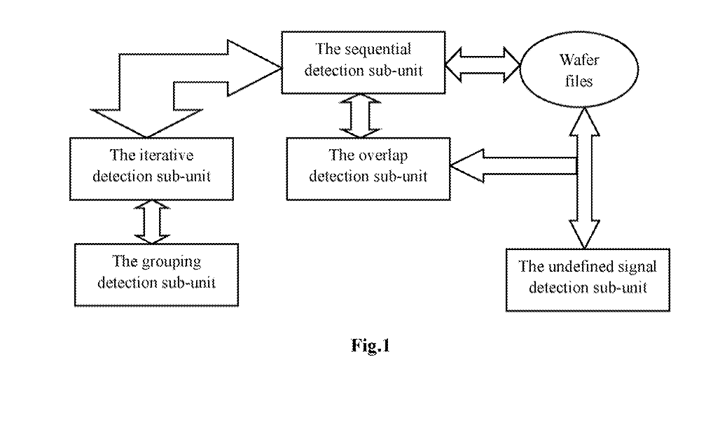

The semiconductor defect signal capturing and statistical system of the present invention includes an on-line monitoring device, a defect signal analytical device, a defect information bank and a defect signal statistical device, the defect signal analytical device is connected with the on-line monitoring device, the defect information bank and the defect signal statistical device respectively, the defect information bank contains several pre-determined defect signal modes, the defect signal analytical device includes a defect signal analysis unit, a defect signal capturing unit and a defect information queue, the defect information bank includes a defect information database and an undefined defect information database, the defect information queue is a defect information database table.

Wherein, the defect signal capturing unit, as shown in FIG. 1, includes a sequential detection sub-unit, an overlap detection sub-unit, an iterative detection sub-unit, a grouping detection sub-unit and an undefined signal detection sub-unit.

The semiconductor defect signal capturing and statistical method carried out with the above mentioned system, mainly comprises the following steps:

(step 1) Scanning semiconductor wafers passing through a production line and grouped by grids, and generating a KLA format wafer defect scanning result file containing corresponding detect signal information with the on-line monitoring device;

(step 2) Analyzing the KLA format wafer defect scanning result file, and capturing detect signals according to the defect information bank with the defect signal analytical device, the information contained in the KLA format wafer defect scanning result file includes grid identifications, slot identifications, processing step identifications, processing device identifications and corresponding defect signal binary information of semiconductor wafers, as shown in (step 2-8), that analyzing the KLA format wafer defect scanning result file, and capturing detect signals according to the defect information bank with the defect signal analytical device comprises the following steps:

(step 2-1) Reading the KLA format wafer defect scanning result file and analyzing the content of the file with the defect signal analysis unit;

(step 2-2) Identifying and capturing corresponding defect signal modes from the defect signal binary information obtained through analysis according to the pre-determined defect signal modes in the defect information bank with the sequential detection sub-unit of the defect signal capturing unit;

(step 2-3) Storing the grid identifications, the slot identifications, the processing step identifications, the corresponding defect signal mode types and the defect signal locations the semiconductor wafers captured correspond to into the defect information queue;

(step 2-4) According to the grid identifications, the slot identifications, the processing step identifications and the processing device identifications the semiconductor wafers captured correspond to, searching for semiconductor wafers with the same grid identifications, the same slot identifications, the same processing step identifications and the same processing device identifications in the semiconductor wafers uncaptured with the iterative detection sub-unit;

(step 2-5) Detecting the semiconductor wafers searched out according to the defect signal modes of the semiconductor wafers captured with the iterative detection sub-unit.

(step 2-6) Identifying the grid identifications, the slot identifications, the processing step identifications and the processing device identifications the semiconductor wafers uncaptured correspond to with the iterative detection sub-unit;

(step 2-7) According to the grid identifications, the slot identifications, the processing step identifications and the processing device identifications identified, searching for semiconductor wafers with the same grid identifications, the same slot identifications, the same processing step identifications and the same processing device identifications in the semiconductor wafers captured with the iterative detection sub-unit;

(step 2-8) Detecting the semiconductor wafers uncaptured according to the defect signal modes of the semiconductor wafers searched out with the iterative detection sub-unit;

(step 2-9) Creating a grouping condition information according to each of the defect signal modes with the grouping detection sub-unit, wherein the grouping condition information includes grouping characteristic parameters of the defect signal mode and the wafer information of the semiconductor wafer the defect signal mode corresponds to;

(step 2-10) According to the defect signal modes the semiconductor wafers captured correspond to, searching for semiconductor wafers with the same defect signal modes and the same wafer information with the grouping detection sub-unit;

(step 2-11) Comparing the wafer information of the semiconductor wafers searched out with the wafer information of the semiconductor wafers captured, if the comparison result meets the grouping characteristic parameters, the semiconductor wafers captured and the semiconductor wafers searched out are grouped into one group;

(step 2-12) Identifying the grid identifications, the slot identifications, the processing step identifications and the processing device identifications the semiconductor wafers uncaptured correspond to with the overlap detection sub-unit;

(step 2-13) Searching for KLA format wafer defect scanning result file with the same grid identifications, the same slot identifications, the same processing step identifications and the same processing device identifications with the overlap detection sub-unit;

(step 2-14) Overlapping the current semiconductor wafer file and the KLA format wafer defect scanning result file searched out to generate a new semiconductor wafer file;

(step 2-15) Returning to the step (1);

(step 2-16) After a pre-determined period of time, extracting the wafer information of the semiconductor wafers uncaptured during this period of time with the undefined signal detection sub-unit;

(step 2-17) Forming an undefined defect signal group using the wafer information having one or more same identifications among the extracted wafer information with the undefined signal detection sub-unit;

(step 2-18) Storing the undefined defect signal group into the undefined defect information database with the undefined signal detection sub-unit;

(step 3) Performing a defect signal statistical process according to the above-processed result with the defect signal statistical device.

In another embodiment, the steps (2-12) to (2-15) in this semiconductor defect signal capturing and statistical method can be replaced by the following steps:

(step 2-12′) According to the grid identifications, the slot identifications, the processing step identifications and the processing device identifications pre-determined, identifying grid identifications, slot identifications, processing step identifications and processing device identifications semiconductor wafers correspond to and same as those predetermined in the semiconductor wafers uncaptured with the overlap detection sub-unit;

(step 2-13′) Adding up the total number of semiconductor wafers identified by the overlap detection sub-units;

(step 2-14′) When the total number of semiconductor wafers added up is up to a pre-determined value, and after a pre-determined period of time, overlapping the semiconductor wafer file identified to generate a new semiconductor wafer file;

(step 2-15′) Returning to the step (1).

In the application of the present invention, the defect signal capturing method in the semiconductor defect signal capturing and statistical method of the present invention is:

According to the obtaining sequence, to the semiconductor wafer files, according to the pre-determined defect signal modes in the defect signal bank, performing the defect signal detection to wafers one by one, and capturing the corresponding defect signal modes.

If the corresponding defect signal modes are matched, storing the grid identifications, the slot identifications, the processing step identifications, the corresponding defect signal mode types and the defect signal locations the semiconductor wafers captured correspond to into the defect information queue.

If the corresponding defect signal modes are not matched, performing the following steps:

Performing the iterative detection, according to the user's settings, a part of the defect signal mode detection supports the iterative detection. If the detect result of the current semiconductor wafer does not match the corresponding defect signal mode, and the defect signal mode supports the iterative detection, moreover the user designates that this defect signal capturing mode needs to use the iterative detection, then according to the grid identifications, the slot identifications, the processing step identifications and the processing device identifications of the current semiconductor wafer file, that whether the semiconductor wafer file with the same grid identifications, the same slot identifications, the same processing step identifications and the same processing device identifications and matching the corresponding defect detection mode is present or not is searched, and according to the detection result of the semiconductor wafer detected, the current signal that does not match the corresponding defect detection mode is subjected to the iterative detection. If the semiconductor wafer file with the same grid identifications, the same slot identifications, the same processing step identifications and the same processing device identifications and matching the corresponding defect detection mode is not searched out, this step is skipped. In addition, when detection result of the current semiconductor wafer matches the corresponding defect signal mode, according to the grid identification, the slot identification, the processing step identification and the processing device identification of the current semiconductor wafer file, that whether the semiconductor wafer file with the same grid identification, the same slot identification, the same processing step identification and the same processing device identification and unmatching the corresponding defect detection mode is present or not is searched, and according to the matching result of the semiconductor wafer matching the defect detection mode, these unmatched semiconductor wafers are subjected to the iterative detection.

Performing the grouping detection, according to each of the defect signal modes, the grouping detection condition can be set independently, which includes grouping characteristic parameters of defect signals and property information of corresponding semiconductor wafers (normally one or more of grid identifications, slot identifications, processing step identifications, and processing device identifications of semiconductor wafers). When a semiconductor wafer matches the corresponding defect detection mode, that whether the wafer information matching the same defect detection mode and the pre-determined property information of semiconductor wafers of which is consistent with that of the current semiconductor wafer is present or not is searched in the defect information bank. If there is such a semiconductor wafer file, the defect signal matching information of the semiconductor wafer is compared with the defect signal matching information of the current semiconductor wafer, if it meets the pre-determined defect signal grouping characteristic parameters, that wafer file would be grouped into a same group.

Performing the overlap detection, with two ways, one of which is to perform the overlap detection through a pre-determined configuration file containing overlap parameters; the other one of which is a planned-task-type triggering overlap detection.

Way 1—according to the grid identifications, the slot identifications, the processing step identifications and the processing device identifications of the current semiconductor wafer file, that whether the semiconductor wafer file with the same grid identifications, the same slot identifications, the same processing step identifications and the same processing device identifications is present or not is searched, if there is such a file and the user sets the overlap detection, the current file is overlapped with a series of files searched out to generate a series of new semiconductor wafer files, and these new files are subjected to the detection of the step 1).

Way 2—according to the processing device identifications, the processing equipment identifications, the processing step identifications, the grid identifications, the wafer number and the time interval given, another time interval is fixed to trigger, wafer files with the given number are overlapped to generate a new wafer file which is subjected to the detection of the step 1. Performing the undefined signal detection, after the completion of all detections mentioned above, there are still some defect signals not contained in the current defined signal modes, in order to solve this problem, it is necessary to use an undefined signal detection sub-unit. The undefined signal detection adopts a time-triggered manner, wherein during the set period of time, according to the scanning time or the detection time of semiconductor wafers, all semiconductor wafer files that do not match defect detection modes in the set period of time are extracted, one or more groups of semiconductor wafer files with the same processing device identifications and the same grid identifications are processed together, to mine one or more undefined signals with same features, which then are stored into the undefined defect signal information bank. The user can register effective defect information into an effective defect detection mode, which can be used as one pre-determined defect detection mode in the subsequent defect signal capturing and detection process.

With the semiconductor defect signal capturing and statistical method of the present invention, for the defect signal capturing unit includes a sequential detection sub-unit, an overlap detection sub-unit, an iterative detection sub-unit, a grouping detection sub-unit and an undefined signal detection sub-unit, after the defect signal binary information of semiconductor wafers obtained by analyzing the KLA file is detected by the sequential detection sub-unit, the semiconductor wafers uncaptured are detected with the overlap detection sub-unit, the iterative detection sub-unit, the grouping detection sub-unit and the undefined signal detection sub-unit, so as to increase the matching probability of defect modes of semiconductor wafers, decrease misreports and reports omitted, then to improve accuracy and integrity of capturing defect signals, causing the semiconductor defect signal capturing and statistical method of the present invention to be able to replace the manual inspection of the prior art substantially, and to decrease the semiconductor manufacturing cost; moreover, the system and the method of the present invention have a simple and efficient operation, stable and reliable working performance, a relatively wide application scope, and not only are suitable for identification, analysis and statistics of defect signals of semiconductor wafers, but also have relatively good practical value for identification and monitoring signal modes of other areas.

In the present specification, the present invention has been described according to the particular embodiments. But it is obvious that these embodiments can be modified or changed without departure from the spirit and scope of the present invention. Therefore, the specification and drawings described above are exemplary only and not intended to be limiting.

1. A semiconductor defect signal capturing and statistical system, including an on-line monitoring device, characterized in that, said system further includes a defect signal analytical device, a defect information bank and a defect signal statistical device, the defect signal analytical device is connected with the on-line monitoring device, the defect information bank and the defect signal statistical device respectively, the defect information bank contains several pre-determined defect signal modes, the defect signal analytical device includes a defect signal analysis unit, a defect signal capturing unit and a defect information queue, the defect signal capturing unit includes a sequential detection sub-unit, an overlap detection sub-unit, an iterative detection sub-unit, a grouping detection sub-unit and an undefined signal detection sub-unit.

2. A semiconductor defect signal capturing and statistical method carried out with the system according to claim 1, characterized in that, the method comprises the following:
Scanning semiconductor wafers passing through a production line and grouped by grids, and generating a KLA format wafer defect scanning result file containing corresponding detect signal information with the on-line monitoring device;
Analyzing the KLA format wafer defect scanning result file and capturing detect signals according to the defect information bank with the defect signal analytical device;
Performing a defect signal statistical process according to the above-processed result with the defect signal statistical device.

3. The semiconductor defect signal capturing and statistical method according to claim 2, characterized in that, the information contained in the KLA format wafer defect scanning result file includes grid identifications, slot identifications, processing step identifications, processing device identifications and corresponding defect signal binary information of semiconductor wafers.

4. The semiconductor defect signal capturing and statistical method according to claim 3, characterized in that, the defect signal capturing unit includes a sequential detection sub-unit, that analyzing the KLA format wafer defect scanning result file, and capturing detect signals according to the defect information bank with the defect signal analytical device comprises the following steps:
(step 2-1) Reading the KLA format wafer defect scanning result file and analyzing the content of the file with the defect signal analysis unit;
(step 2-1) Identifying and capturing corresponding defect signal modes from the defect signal binary information obtained through analysis according to the pre-determined defect signal modes in the defect information bank with the sequential detection sub-unit of the defect signal capturing unit;
(step 2-3) Storing the grid identifications, the slot identifications, the processing step identifications, the corresponding defect signal mode types and the defect signal locations the semiconductor wafers captured correspond to into the defect information queue.

5. The semiconductor defect signal capturing and statistical method according to claim 4, characterized in that, the defect signal capturing unit further includes an iterative detection sub-unit, and after the step (2-3), this method further comprises the following steps:
(step 2-4) According to the grid identifications, the slot identifications, the processing step identifications and the processing device identifications the semiconductor wafers captured correspond to, searching for semiconductor wafers with the same grid identifications, the same slot identifications, the same processing step identifications and the same processing device identifications in the semiconductor wafers uncaptured with the iterative detection sub-unit;
(step 2-5) Detecting the semiconductor wafers searched out according to the defect signal modes of the semiconductor wafers captured with the iterative detection sub-unit.

6. The semiconductor defect signal capturing and statistical method according to claim 5, characterized in that, after the step (2-5), this method further comprises the following steps:
(step 2-6) Identifying the grid identifications, the slot identifications, the processing step identifications and the processing device identifications the semiconductor wafers uncaptured correspond to with the iterative detection sub-unit;
(step 2-7) According to the grid identifications, the slot identifications, the processing step identifications and the processing device identifications identified, searching for semiconductor wafers with the same grid identifications, the same slot identifications, the same processing step identifications and the same processing device identifications in the semiconductor wafers captured with the iterative detection sub-unit;
(step 2-8) Detecting the semiconductor wafers uncaptured according to the defect signal modes of the semiconductor wafers searched out with the iterative detection sub-unit.

7. The semiconductor defect signal capturing and statistical method according to claim 6, characterized in that, the defect signal capturing unit further includes a grouping detection sub-unit, and after the step (2-8), this method further comprises the following steps:
(step 2-9) Creating a grouping condition information according to each of the defect signal modes with the grouping detection sub-unit, wherein the grouping condition information includes grouping characteristic parameters of the defect signal mode and the wafer information of the semiconductor wafer the defect signal mode corresponds to;
(step 2-10) According to the defect signal modes the semiconductor wafers captured correspond to, searching for semiconductor wafers with the same defect signal modes and the same wafer information with the grouping detection sub-unit;
(step 2-11) Comparing the wafer information of the semiconductor wafers searched out with the wafer information of the semiconductor wafers captured, if the comparison result meets the grouping characteristic parameters, the semiconductor wafers captured and the semiconductor wafers searched out are grouped into one group.

8. The semiconductor defect signal capturing and statistical method according to claim 7, characterized in that, the defect signal capturing unit further includes an overlap detection sub-unit, and after (step 2-11), this method further comprises the following steps:
(step 2-12) Identifying the grid identifications, the slot identifications, the processing step identifications and the processing device identifications the semiconductor wafers uncaptured correspond to with the overlap detection sub-unit;
(step 2-13) Searching for KLA format wafer defect scanning result file with the same grid identifications, the same slot identifications, the same processing step identifications and the same processing device identifications with the overlap detection sub-unit;
(step 2-14) Overlapping the current semiconductor wafer file and the KLA format wafer defect scanning result file searched out to generate a new semiconductor wafer file;
(step 2-15) Returning to the step (1).

9. The semiconductor defect signal capturing and statistical method according to claim 7, characterized in that, the defect signal capturing unit further includes an overlap detection sub-unit, and after (step 2-11), this method further comprises the following steps:
(step 2-12′) According to the grid identifications, the slot identifications, the processing step identifications and the processing device identifications pre-determined, identifying grid identifications, slot identifications, processing step identifications and processing device identifications semiconductor wafers correspond to and same as those predetermined in the semiconductor wafers uncaptured with the overlap detection sub-unit;
(step 2-13′) Adding up the total number of semiconductor wafers identified by the overlap detection sub-units;
(step 2-14′) When the total number of semiconductor wafers added up is up to a pre-determined value, and after a pre-determined period of time, overlapping the semiconductor wafer file identified to generate a new semiconductor wafer file;
(step 2-15′) Returning to the step (1).

10. The semiconductor defect signal capturing and statistical method according to claim 8 or claim 9, characterized in that, the defect signal capturing unit further includes an undefined signal detection sub-unit, the defect information bank includes a defect information database and an undefined defect information database, and after (step 2-15) or (step 2-15′), this method further comprises the following steps:
(step 2-16) After a pre-determined period of time extracting the wafer information of the semiconductor wafers uncaptured during this period of time with the undefined signal detection sub-unit;
(step 2-17) Forming an undefined defect signal group using the wafer information having one or more same identifications among the extracted wafer information with the undefined signal detection sub-unit;
(step 2-18) Storing the undefined defect signal group into the undefined defect information database with the undefined signal detection sub-unit.

11. The semiconductor defect signal capturing and statistical method according to claim 10, characterized in that, the period of time is the scanning or detecting time of semiconductor wafers.
